(19) United States
(12) Patent Application Publication
(10) Pub. No.: US 2026/0011678 A1
(43) Pub. Date: Jan. 8, 2026

(54) SEMICONDUCTOR PACKAGE STRUCTURE

(71) Applicant: Airoha Technology Corp., Hsinchu (TW)

(72) Inventors: Ming-Tzong YANG, Hsinchu (TW); Cheng-Hao CHANG, Hsinchu (TW); Chi-Fu HSU, Hsinchu (TW); Cheng-Chou HUNG, Hsinchu (TW)

(21) Appl. No.: 18/764,898

(22) Filed: Jul. 5, 2024

(51) Int. Cl. H01L 23/00; H01L 23/31; H01L 23/498

(52) U.S. Cl. CPC H01L 24/48; H01L 23/3135; H01L 23/49816; H01L 24/26; H01L 24/32; H01L 24/73; H01L 2224/26175; H01L 2224/32225; H01L 2224/48227; H01L 2224/73265; H01L 2924/15153

(57) ABSTRACT

A semiconductor package structure is provided. The semiconductor package structure includes a semiconductor die, a package substrate, and at least one bonding wire. The package substrate includes a dam structure to define a space where the semiconductor die is placed. The bonding wire is electrically connected between the semiconductor die and the package substrate.

### BACKGROUND OF THE INVENTION

### Field of the Invention

The disclosure relates to a semiconductor package technology, and in particular to a semiconductor package structure with short signal propagation path.

### Description of the Related Art

Semiconductor packages protect semiconductor dies from environmental contaminants. They also provide an electrical connection between a semiconductor die and a substrate, such as a printed circuit board (PCB). For example, a semiconductor die may be enclosed in an encapsulating material, and traces are electrically connected to the semiconductor die and the substrate.

In the semiconductor packaging industry, there is a trend to improve the operating speed, the performance, and the heat dissipation of the semiconductor package and reduce the thickness of the semiconductor package and the manufacturing cost. To accomplish this, various semiconductor package designs have been developed.

Although existing semiconductor package structures are generally adequate for their intended purposes, they have not been satisfactory in all respects. Therefore, the design of semiconductor package structures remains a critical issue.

### BRIEF SUMMARY OF THE INVENTION

In some embodiments, a semiconductor package structure is provided. The semiconductor package structure includes a semiconductor die, a package substrate, and at least one bonding wire. The package substrate includes a dam structure that extends along the peripheral edge of the semiconductor die. The bonding wire is electrically connected between the semiconductor die and the package substrate.

In some embodiments, a semiconductor package structure is provided. The semiconductor package structure includes a semiconductor die, a package substrate, and at least one bonding wire. The package substrate has a cavity that extends from the top surface of the package substrate toward the bottom surface of the package substrate. The semiconductor die is disposed on the bottom surface of the cavity. The depth of the cavity is substantially equal to the thickness of the semiconductor die.

In some embodiments, a semiconductor package structure is provided. The semiconductor package structure includes an encapsulating layer, a semiconductor die, a package substrate, and at least one bonding wire. The encapsulating layer includes a lower portion having a first width and an upper portion extending from a top of the lower portion and having a second width that is wider than the first width. The package substrate surrounds the lower portion of the encapsulating layer and is covered by the upper portion of the encapsulating layer. The semiconductor die is disposed in the lower portion of the encapsulating layer, wherein the bottom surface of the semiconductor die is exposed from the lower portion of the encapsulating layer. The bonding wire is enclosed in the upper portion of the encapsulating layer and is electrically connected between the semiconductor die and the package substrate.

### BRIEF DESCRIPTION OF THE DRAWINGS

The present disclosure can be more fully understood by reading the subsequent detailed description and examples with references made to the accompanying drawings, wherein:

FIG. 1 illustrates a cross-sectional view of a semiconductor package structure in accordance with some embodiments.

FIG. 2 illustrates a cross-sectional view of a semiconductor package structure in accordance with some embodiments.

FIG. 3 illustrates a cross-sectional view of a semiconductor package structure in accordance with some embodiments.

### DETAILED DESCRIPTION OF THE INVENTION

The following description is made for the purpose of illustrating the general principles of the invention and should not be taken in a limiting sense. The scope of the invention is best determined by reference to the appended claims.

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed.

The bonding wires in a semiconductor package have a long signal propagation path and high electrical resistance. As a result, semiconductor packages suffer from signal integrity issues. In addition, the lengthy signal propagation path can reduce the operating speed and the performance of the semiconductor package. Accordingly, a novel semiconductor package structure that is capable of addressing or improving upon the aforementioned problems is desired.

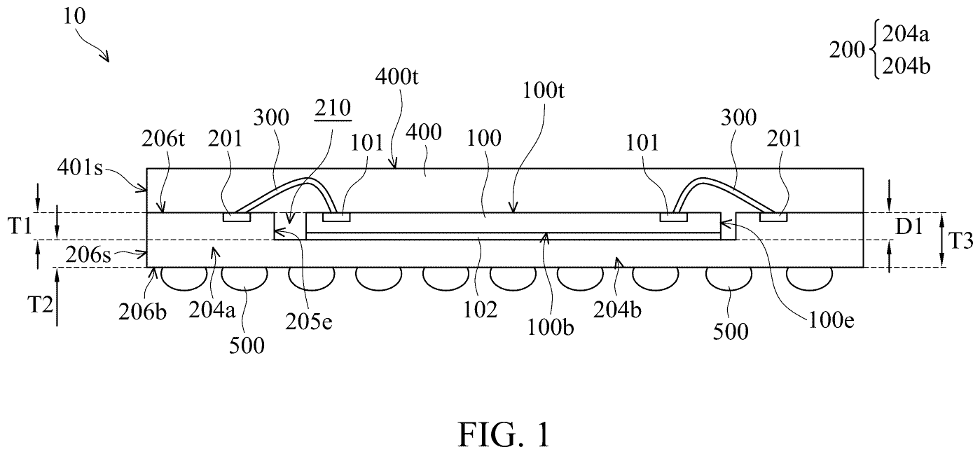

FIG. 1 illustrates a cross-sectional view of a semiconductor package structure 10 in accordance with some embodiments. The semiconductor package structure 10 includes a semiconductor die (which is sometimes referred to as an integrated circuit (IC) die) 100, a package substrate 200, and one or more bonding wires 300. The semiconductor die 100 is attached to a package substrate 200 in, for example, a “wire-bonding” configuration. In the wire-bonding configuration, bonding wires 300 are formed between conductive pads 101 (which is sometimes referred to as terminals) of the semiconductor die 100 and the conductive pads 201 of the package substrate 200, so that the bonding wires 300 are electrically connected between the semiconductor die 100 and the package substrate 200.

As shown in FIG. 1, the conductive pads 101 are formed on the top surface 100t (which may be referred to as a front-side) of the semiconductor die 100. The top surface 100t serves as an active surface. Further, conductive pads 201 are formed on a top surface of the package substrate 200. As a result, each bonding wire 300 is physically connected between the corresponding pad 101 on the top surface 100t of the semiconductor die 100 and the corresponding pad 201 on the surface of package substrate 200.

The semiconductor die 100 may be any types of well-known semiconductor die. For example, the semiconductor die 100 may be a radio-frequency IC (RFIC) die, a microprocessor die, an application-specific integrated circuit (ASIC), a system-on-chip (SoC) die, a base-band IC die, or a memory die or the like according to various embodiments.

The package substrate 200 may be one of the various types of substrates known to those skilled in the art (e.g., organic or inorganic substrates). Further, the package substrate 200 may include one or more metal layers (not shown) with one or more dielectric layers (not shown). The dielectric layers may include polyimide, polymer, epoxy, or the like or any suitable dielectric material. Traces may be made in the metal layers by, for example, etching the metal layers for using in signal, ground, and/or power routing. The package substrate 200 may also be a silicon interposer and made of one or more metal layers with one or more dielectric layers. For example, the package substrate 200 is a multi-layer substrate including at least one metal layer interposed between two dielectric layers.

As shown in FIG. 1, in some embodiments, the package substrate 200 includes a dam structure 204a and a carrier portion 204b. The dam structure 204a of the package substrate 200 extends along and is spaced apart from the peripheral edge 100e of the semiconductor die 100. The carrier portion 204b of the package substrate 200 is adjacent to the lower part of the inner edge 205e of the dam structure 204a. Further, the carrier portion 204b is extended from and surrounded by the inner edge 205e of the dam structure 204a. As a result, the dam structure 204a and the carrier portion 204b of the package substrate 200 form a cavity 210 in the package substrate 200. This cavity 210 extends from the top surface of the package substrate (e.g., the top surface 206t of the dam structure 204a) toward the bottom surface of the package substrate 200 (e.g., the bottom surface 206b of the dam structure 204a). In some embodiments, the cavity 210 in the package substrate 200 defines a space for the placement of the semiconductor die 100.

The semiconductor die 100 disposed in the cavity 210 of the package substrate 200 is attached to the bottom surface of the cavity 210 (i.e., the top surface of the carrier portion 204b) of the package substrate 200. In some embodiments, the semiconductor die 100 includes an adhesion layer 102 on the bottom surface 100b (which is sometime referred to as a backside or a non-active surface) of the semiconductor die 100, so that semiconductor die 100 is attached to the top of the carrier portion 204b of the package substrate 200. For example, the adhesion layer 102 may be made of epoxy or the like, such as a die attach film (DAF).

In some embodiments, the thickness T1 of the semiconductor die 100 including the thin adhesion layer 102 can be adjusted, so that the depth D1 of the cavity 210 of the package substrate 200 is substantially equal to the thickness T1 of the semiconductor die 100 including the thin adhesion layer 102. In other words, the sum of the thickness T1 and the thickness T2 of the carrier portion 204b is substantially equal to the thickness T3 of the dam structure 204a. As a result, the top surface 206t of the dam structure 204a of the package substrate 200 is substantially level with the top surface 100t of the semiconductor die 100.

In a case where a semiconductor die is disposed on a flat package substrate without any cavity therein, such that a top surface of the semiconductor die is higher than a top surface of the flat package substrate by at least the thickness of the semiconductor die, the bonding wire must be at least longer than the thickness of the semiconductor die in order to extend from a top surface of the semiconductor die to a top surface of the flat package substrate for electrical connection. However, in the semiconductor package structure 10, the length of the bonding wires 300 can be reduced because the top surface 206t of the dam structure 204a is substantially level with the top surface 100t of the semiconductor die 100. As a result, the signal propagation path can be reduced, thereby increasing the operating speed and performance of the semiconductor package and reducing the manufacturing cost.

As shown in FIG. 1, in some embodiments, the semiconductor package structure 10 further includes an encapsulating layer 400 that covers the package substrate 200. The semiconductor die 100 and the bonding wires 300 are covered by and enclosed in the encapsulating layer 400. In some embodiments, the encapsulating layer 400 also extends into the cavity 210 of the package substrate 200 and surrounds the semiconductor die 100. More specifically, the encapsulating layer 400 fully fills the gap formed between the dam structure 204a of the package substrate 200 and the semiconductor die 100, so as to separate the inner edge 205e of the dam structure 204a of the package substrate 200 from the peripheral edge 100e of the semiconductor die 100.

As shown in FIG. 1, in some embodiments, the outer sidewall surface 401s of the encapsulating layer 400 is vertically aligned to the outer sidewall surface 206s of the package substrate 200. In some embodiments, the encapsulating layer 400 has a flat top surface, so that the distance between the top surface of the package substrate 200 (e.g., the top surface 206t of the dam structure 204a) and the top surface 400t of the encapsulating layer 400 is substantially equal to the distance between the top surface 100t of the semiconductor die 100 and the top surface 400t of the encapsulating layer 400. The encapsulating layer 400 may include a molding compound material. The molding compound material may be a polymer material, such as an epoxy-based resin, or the like.

In a case where a semiconductor die is disposed on a flat package substrate without any cavity therein, a thickness of an encapsulating layer, measured from a flat surface of the flat package substrate, must be at least thicker than the thickness of the semiconductor die to ensure the semiconductor die is fully encapsulated. However, in the semiconductor package structure 10, the thickness of the portion of the encapsulating layer 400 above the package substrate 200, measured from the top surface 206t of the dam structure 204a, can be reduced because the semiconductor die 100 is disposed in the cavity 210 of the package substrate 200. This reduction in thickness makes the semiconductor package structure 10 thinner, thereby improving heat dissipation of the semiconductor die 100 in the semiconductor package structure 10. Moreover, compare to such a case, the size (e.g., the height) of the semiconductor package structure 10 can be reduced and the manufacturing cost can be reduced further.

Referring to FIG. 1 again, in some embodiments, the semiconductor package structure 10 further includes conductive connectors 500 formed on the bottom surface 206b of the package substrate 200. The conductive connectors 500 are electrically connected to the semiconductor die 100 via the package substrate 200 and the bonding wires 300. The conductive connectors 500 are employed to electrically couple the semiconductor die 110 to an external circuit (not shown), such as a printed circuit board (PCB) or a main board. The conductive connectors 500 may include solder balls, solder bumps, copper posts, copper bumps, gold bumps, or any suitable conductive connector. In some embodiments, the conductive connectors 500 are solder balls.

Similarly, when the semiconductor die 100 is disposed in the cavity 210 of the package substrate 200, the distance between the top surface 100t of the semiconductor die 100 and the top surface of external circuit (e.g., PCB or a main board) (i.e., another one of the heat dissipation paths of the semiconductor die 100), which contacts with conductive connectors 500, can also be reduced. As a result, the heat dissipation of the semiconductor die 100 in the semiconductor package structure 10 can be improved further.

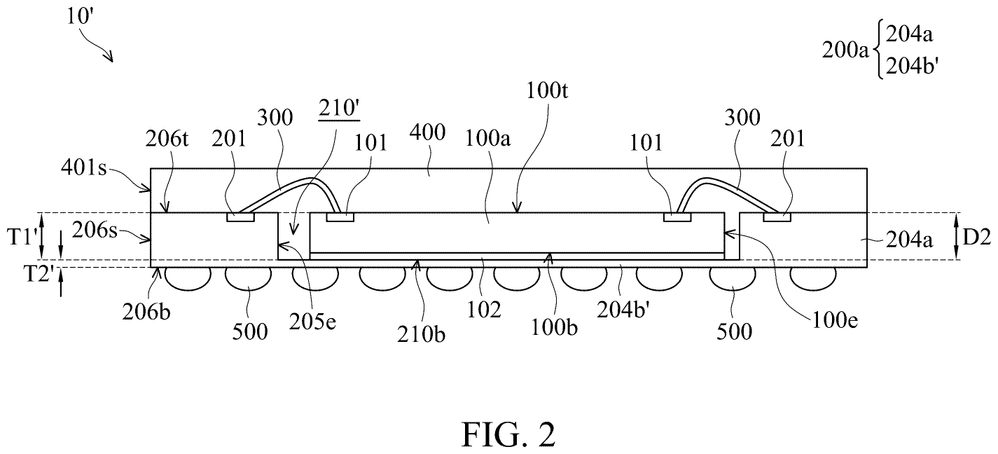

FIG. 2 illustrates a cross-sectional view of a semiconductor package structure 10′ in accordance with some embodiments. Descriptions of elements of the embodiments hereinafter that are the same as or similar to those previously described with reference to FIG. 1 may be omitted for brevity. In some embodiments, the semiconductor package structure 10′ shown in FIG. 2 is similar to the semiconductor package structure 10 shown in FIG. 1. The difference is the depth of cavity and the thickness of the semiconductor die, but the top surface 206t of the dam structure 204a of the package substrate 200 is substantially level with the top surface 100t of the semiconductor die 100. More specifically, the package substrate 200a of the semiconductor package structure 10′ includes a dam structure 204a and a carrier portion 204b′. The dam structure 204a and the carrier portion 204b′ of the package substrate 200a form a cavity 210′ in the package substrate 200a. In some embodiments, the depth D2 of the cavity 210′ of the package substrate 200a is deeper than the depth D1 of the cavity 210 shown in FIG. 1. Further, the thickness T1′ of the semiconductor die 100a including the thin adhesion layer 102 is thicker than the thickness T1 shown in FIG. 1. As a result, the thickness T2′ of the carrier portion 204b is thinner than the thickness T2 of the carrier portion 204b shown in FIG. 1. Further, the depth D2 of the cavity 210′ of the package substrate 200a is substantially equal to the thickness T1′ of the semiconductor die 100a including the thin adhesion layer 102.

Since the thickness T2′ of the carrier portion 204b is thinner than the thickness T2 of the carrier portion 204b shown in FIG. 1, the distance between the top surface 100t of the semiconductor die 100a and the top surface of external circuit (e.g., PCB or a main board) can be reduced further. As a result, the heat dissipation of the semiconductor die 100a in the semiconductor package structure 10′ can be improved further.

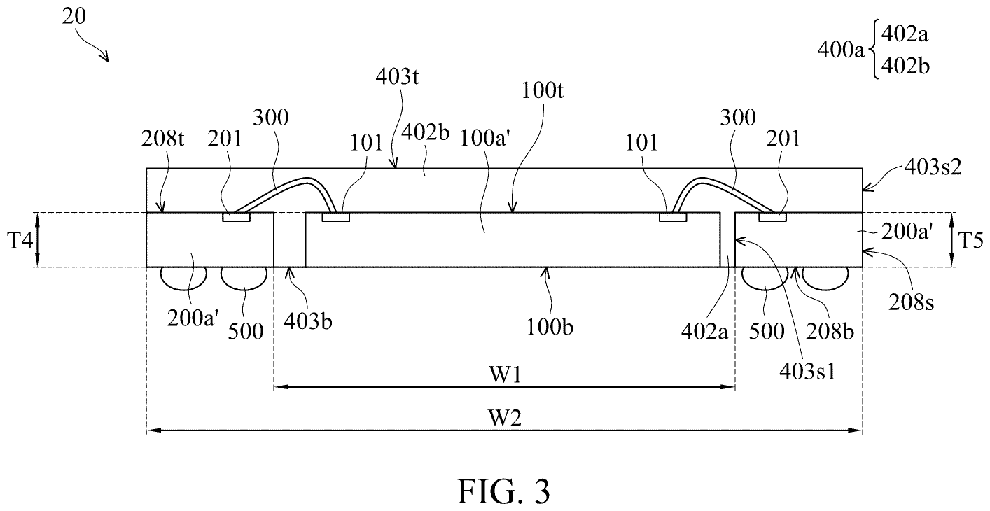

FIG. 3 illustrates a cross-sectional view of a semiconductor package structure 20 in accordance with some embodiments. Descriptions of elements of the embodiments hereinafter that are the same as or similar to those previously described with reference to FIG. 1 or 2 may be omitted for brevity. In some embodiments, the semiconductor package structure 20 shown in FIG. 3 is similar to the semiconductor package structure 10 shown in FIG. 1 and the semiconductor package structure 10′ shown in FIG. 2. The difference is the semiconductor die 100a′ passes through the package substrate 200a′ in the semiconductor package structure 20 (i.e., the semiconductor die 100a′ is placed in an opening in the semiconductor package structure 20), but the top surface 208t of the package substrate 200a′ is substantially level with the top surface 100t of the semiconductor die 100a′.

More specifically, the semiconductor package structure 20 includes a semiconductor die 100a′, a package substrate 200a′, bonding wires 300, and an encapsulating layer 400a. Referring to FIG. 3, in some embodiments, the encapsulating layer 400a includes a lower portion 402a, and an upper portion 402b extending from a top of the lower portion 402a. The lower portion 402a has a first width W1, and the upper portion 402b has a second width W2 that is wider than the first width W1. As a result, the sidewall surface 403s2 of the upper portion 402b of the encapsulating layer 400a laterally protrudes from the sidewall surface 403s1 of the lower portion 402a of the encapsulating layer 400a, as shown in FIG. 3.

Referring to FIG. 3 again, in some embodiments, the package substrate 200a′ has a ring shape as viewed form a top-view perspective, so that the package substrate 200a′ is formed as a dam structure as viewed form a side-view perspective. The ring-shaped package substrate 200a′ surrounds and is in direct contact with the sidewall surface 403s1 of the lower portion 402a of the encapsulating layer 400a. Further, the laterally protruding part of the upper portion 402b of the encapsulating layer 400a covers and is in direct contact with the top surface 208t of the package substrate 200a′. In some embodiments, the sidewall surface 403s2 of the upper portion 402b of the encapsulating layer 400a is vertically aligned to the outer sidewall surface 208s of the package substrate 200a′.

In some embodiments, the semiconductor die 100a′ is disposed in the lower portion 402a of the encapsulating layer 400a. In other words, the lower portion 402a of the encapsulating layer 400a has a cavity (not shown) that extends from the bottom surface 403b of the lower portion 402a of the encapsulating layer 400a toward the top surface 403t of the upper portion 402b of the encapsulating layer 400a. Further, the bottom surface 100b of the semiconductor die 100a′ is exposed from the lower portion 402a of the encapsulating layer 400a.

As shown in FIG. 3, in some embodiments, the top surface 100t of the semiconductor die 100a′ is substantially level with the bottom surface of the upper portion 402b of the encapsulating layer 400a and the top surface 208t of the package substrate 200a′. Further, the bottom surface 100b of the semiconductor die 100a′ is substantially level with the bottom surface 403b of the lower portion 402a of the encapsulating layer 400a and the bottom surface 208b of the package substrate 200a′. As a result, the semiconductor die 100a′ and the lower portion 402a of the encapsulating layer 400a pass through the package substrate 200a′. Moreover, the thickness T4 of the semiconductor die 100a′ is substantially equal to the thickness T5 of the package substrate 200a′ (i.e., the dam structure).

In some embodiments, the bonding wires 300 are enclosed in the upper portion 402b of the encapsulating layer 400a and electrically connected between the semiconductor die 100a′ and the package substrate 200a′.

In some embodiments, the semiconductor package structure 20 further includes conductive connectors 500. The conductive connectors 500 are formed on the bottom surface 208b of the package substrate 200a′.

In the semiconductor package structure 20, the semiconductor die 100a′ passes through the package substrate 200a′ to expose the bottom surface 100b from the bottom surface 208b of the package substrate 200a′. Therefore, the distance between the top surface 100t of the semiconductor die 100a′ and the top surface of external circuit (e.g., PCB or a main board) can be reduced further, compared to a case where a semiconductor die is disposed on a flat package substrate without any cavity therein. As a result, compare to the semiconductor package structure 10′ shown in FIG. 2, the heat dissipation of the semiconductor die 100a′ in the semiconductor package structure 20 can be improved further.

According to the foregoing embodiments, the semiconductor package structure is designed to form a space or cavity in the package substrate for placement of the semiconductor die. In the semiconductor package structure, it allows that the height of the bonding wire, measured from the conductive pad disposed on the package substrate to the highest portion of the bonding wire in a direction extending from the top surface of the package substrate to the top surface of the upper portion of the encapsulating layer, can be effectively reduced. Further, it also allows the distance from the top surface of the semiconductor die to the top surface of the encapsulating layer and the distance from the top surface of the semiconductor die to an underlying external circuit (e.g., PCB or a main board) can be effectively reduced. Compare to the semiconductor die disposed on the top surface of a flat package substrate without any cavity therein, the signal propagation path can be effectively reduced, thereby increasing the operating speed and performance of the semiconductor package and reducing the manufacturing cost of the semiconductor package. Moreover, in the semiconductor package structure, it allows that the distance from the top surface of the semiconductor die to the top surface of the encapsulating layer and the distance from the top surface of the semiconductor die to the top surface of external circuit can be effectively reduced, thereby improving the heat dissipation of the semiconductor package.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a semiconductor die;
a package substrate comprising a dam structure that extends along a peripheral edge of the semiconductor die; and
at least one bonding wire electrically connected between the semiconductor die and the package substrate.

2. The semiconductor package structure as claimed in claim 1, wherein a top surface of the dam structure is substantially level with the top surface of the semiconductor die.

3. The semiconductor package structure as claimed in claim 1, wherein a thickness of the semiconductor die is substantially equal to a thickness of the dam 2 structure.

4. The semiconductor package structure as claimed in claim 1, further comprising:
an encapsulating layer covering the package substrate, wherein the semiconductor die and the bonding wire are enclosed in the encapsulating layer.

5. The semiconductor package structure as claimed in claim 4, wherein the encapsulating layer separates an inner edge of the dam structure from the peripheral edge of the semiconductor die.

6. The semiconductor package structure as claimed in claim 1, wherein the package substrate further comprises a carrier portion adjacent to and surrounded by an inner edge of the dam structure and wherein the semiconductor die is attached to the carrier portion.

7. The semiconductor package structure as claimed in claim 6, wherein a sum of a thickness of the semiconductor die and a thickness of the carrier portion is substantially equal to a thickness of the dam structure.

8. A semiconductor package structure, comprising:
a package substrate having a cavity that extends from a top surface of the package substrate toward a bottom surface of the package substrate;
a semiconductor die disposed on a bottom surface of the cavity, wherein a depth of the cavity is substantially equal to a thickness of the semiconductor die; and
at least one bonding wire enclosed in the encapsulating layer and electrically connected between the semiconductor die and the package substrate.

9. The semiconductor package structure as claimed in claim 8, further comprising:
an encapsulating layer covering the package substrate and the semiconductor die, wherein the bonding wire is enclosed in the encapsulating layer.

10. The semiconductor package structure as claimed in claim 9, wherein a sidewall surface of the encapsulating layer is vertically aligned to an outer sidewall surface of the package substrate.

11. The semiconductor package structure as claimed in claim 9, wherein the encapsulating layer extends into the cavity and surrounds the semiconductor die.

12. The semiconductor package structure as claimed in claim 8, wherein a distance between the top surface of the package substrate and a top surface of the encapsulating layer is substantially equal to a distance between a top surface of the semiconductor die and the top surface of the encapsulating layer.

13. The semiconductor package structure as claimed in claim 8, further comprising:
a plurality of conductive connectors formed on the bottom surface of the package substrate.

14. A semiconductor package structure, comprising:
an encapsulating layer comprising:
a lower portion having a first width; and
an upper portion extending from a top of the lower portion and having a second width that is wider than the first width;
a package substrate surrounding the lower portion of the encapsulating layer and covered by the upper portion of the encapsulating layer;
a semiconductor die disposed in the lower portion of the encapsulating layer, wherein a bottom surface of the semiconductor die is exposed from the lower portion of the encapsulating layer; and
at least one bonding wire enclosed in the upper portion of the encapsulating layer and electrically connected between the semiconductor die and the package substrate.

15. The semiconductor package structure as claimed in claim 14, further comprising:
a plurality of conductive connectors formed on a bottom surface of the package substrate.

16. The semiconductor package structure as claimed in claim 14, wherein a sidewall surface of the upper portion of the encapsulating layer is vertically aligned to an outer sidewall surface of the package substrate.

17. The semiconductor package structure as claimed in claim 7, wherein the bottom surface of the semiconductor die is substantially level with a bottom surface of the lower portion of the encapsulating layer and a bottom surface of the package substrate.

18. The semiconductor package structure as claimed in claim 14, wherein a top surface of the package substrate is substantially level with a top surface of the semiconductor die.

19. The semiconductor package structure as claimed in claim 14, wherein a thickness of the semiconductor die is substantially equal to a thickness of the package substrate.
